(19) United States
(12) Patent Application Publication
(10) Pub. No.: US 2006/0132167 A1
(43) Pub. Date: Jun. 22, 2006

(54) Contactless wafer level burn-in

(76) Inventor: Jian Chen, San Jose, CA (US)

Correspondence Address: VIERRA MAGEN MARCUS & DENIRO LLP, 575 MARKET STREET SUITE 2500, SAN FRANCISCO, CA, 94105, US

(21) Appl. No.: 11/021,688

(22) Filed: Dec. 22, 2004

(51) Int. Cl. G01R 31/26

(52) U.S. Cl. 324/765

(57) ABSTRACT

A method and apparatus for performing a wafer-level burn-in. The method comprises the steps of providing the wafer into a burn-in chamber; and outputting a power and a test initiation signal to a wafer via a wireless signal. The apparatus includes a test chamber, a transport mechanism in the test chamber, a temperature control apparatus in the test chamber, and an RF transponder in the chamber.

### BACKGROUND OF THE INVENTION

1. Field of the Invention

The present invention is directed to apparatus and methods for ensuring reliability in semiconductor devices, and particularly for providing wafer level burn-in.

2. Description of the Related Art

Semiconductor wafers typically comprise a plurality of substantially isolated “die” or “chips” containing circuitry, separated from each other by scribe line areas. In the normal integrated circuit production flow, an integrated wafer that has completed fabrication is cut into many individual die. The individual die contained within the wafer are separated by sawing and packaged individually or in multi-chip modules. These die are then mounted into individual sockets that can then be burned-in and tested using standard test equipment and fixtures.

The demand for smaller and smaller consumer devices, such as wireless telephones and PDAs, has led to smaller semiconductor device packages and even to the use of bare (unpackaged) die in some devices.

Not all die on a particular semiconductor wafer are completely functional; some have manufacturing defects. Certain defects do not reveal themselves immediately after fabrication. For example, an insulating oxide layer between two conductors may be excessively thin in a particular region. Voltage and temperature stress will cause the particular region of excessively thin insulating oxide to break down, resulting in a short circuit between the two conductors which can be detected during electrical testing.

If manufactures are able to utilize known good die (KGD), the cost of replacing failed, packaged parts can be greatly reduced. KGD generally refers to a die level product provided by an IC manufacturer. A common use of bare die is in the production of Multi-Chip Modules (MCMs). Producing MCMs with a low failure rate is helped by using KGD. KGD is advantageous to the manufacturing of MCMs because of the number of die on an MCM and the difficulties in repairing an MCM. The failure rate of an MCM increases with the number of die on the MCM. Full burn-in and testing of the die prior to assembly in the MCM can have a significant impact on the yield and reliability of the MCM.

Approaches for achieving KGD vary by device type and by die manufacturer, but can include wafer level electrical testing, including techniques that build in test structures, and die level testing using temporary, semipermanent and permanent packaging techniques.

At the end of a manufacturing process, manufactures may perform a number of different performance tests on products. Standard methods of performing burn-in and other manufacturing tests on devices requires dies to be packaged and tested using Automated Test Equipment (ATE). For burn in testing, good devices are then placed into sockets mounted on custom designed burn-in boards. These burn-in sockets are designed specifically for high temperature applications. The loaded boards are then mounted into large chambers that control ambient temperature and provide a means for interfacing stimulus to the packages.

At this point test vectors are used to stimulate the devices and a test routine is run for a number of hours as dictated in a qualification specification.

One example of a method of achieving KGD is wafer level burn-in. The wafer level burn-in test involves testing whole, or parts of whole, wafers containing integrated circuits before segmenting the integrated circuits from the wafer. Generally, to perform wafer testing, the wafer is manufactured with test points and a test apparatus is formed to contact the test points allowing test signals to propagate from a signal source through the test apparatus and onto the integrated circuits. The test points may be formed onto the integrated circuit itself, or disposed remotely with respect thereto to minimize the damage to the integrated circuit by the test apparatus. After burn-in the parts are unloaded and re-tested using ATE. To achieve high though put in such testing, custom probe cards are used to contact large numbers of dies simultaneously. Typically functional gross failures occur within the first 48 hours of stress testing with elevated ambient temperature of 125° C. and voltage levels 10% above nominal operating values. As failure data is analyzed, and manufacturing parameters adjusted, and the process becomes more mature the defect levels can be reduced.

A drawback with prior art wafer level burn-in concerns mismatch between the coefficients of thermal expansion of the test apparatus and the wafer during burn-in, as well as the adverse effects of a defective test apparatus during burn-in. For example, it is often difficult to determine whether an integrated circuit identified as being defective is a result of a defect in the integrated circuit or a defective test apparatus, resulting in a entire wafer of operational integrated circuits being improperly discarded. In addition, a defective test apparatus can result in catastrophic failure rendering the entire wafer defective.

Perhaps the most significant hurdle in wafer level burn-in, or indeed any testing, is providing a contact method for interfacing the test electronics with the I/O pads and power planes at the individual die level. The issue of interfacing test electronics to the device under test at the wafer level faces stiff challenges, particularly relating to test capability, power dissipation, voltage rail tolerances, physical limitations (large quantity of die to be tested in a small working area), cost effective engineering, sustainable quality and correlation to ATE results.

Each approach to the issue of interfacing with the wafer must provide the necessary pin/pad assignment to perform sufficient test routines in order to qualify the bare die's KGD. There are three distinct approaches to achieving this requirement. One method is to make contact with all relevant pads on each die. The second method involves the use of modified probe hardware. The third approach is to limit the number of interface connections to a manageable size and re-direct the interface design onto a sacrificial metal layer applied directly above the passivation layer on the wafer. In current methods, contact with the pads must be maintained during both when conducting the test and determining the results of the test.

During such testing, probe cards for each type of product must also be made. Probe cards are very expensive to make. In some cases, there may be, for example, 130 pins and 500 dies per wafer requiring testing. This may result in significant financial and time resources being required to build one probe card. Such resources are again expended when the die changes as a result of different densities or product configurations.

A solution to the aforementioned issues would provide significant cost savings to manufacturers.

### SUMMARY OF THE INVENTION

The present invention, roughly described, pertains to a method and apparatus for improving device testing. In one aspect, the invention comprises a method for performing a wafer-level built-in test. The method comprises the steps of providing the wafer into a test chamber; and outputting a power and a test initiation signal to a wafer via a wireless signal. In one aspect, the step of outputting includes outputting a signal initiating a device stress test sequence on the wafer, and in a further aspect, may comprise generating an RF signal in the chamber.

In yet another aspect, the invention is a method for providing a wafer lever built-in test process. The method may comprise the steps of providing a built-in test circuit on the wafer; and providing an RF interface on the wafer coupled to the built in test circuit. In a further aspect, the step of providing a built-in test circuit on the wafer includes providing a power extraction component and a demodulator.

In a further aspect, the invention comprises a semiconductor wafer. In this aspect, the wafer includes at lease one built-in stress control circuit coupled to a device on the wafer; and an RF interface coupled to provide power and a data signal to the BIST circuit. The wafer may include a plurality of devices and a built-in stress control circuit is provided for each device on the wafer.

In yet another aspect, the invention is a semiconductor wafer including a plurality of dies, each die separated by a scribe line. The invention includes at least on RF interface circuit provided on the wafer; at least one scribe line RF antenna coupled to the at least one RF interface circuit; and at least one burn-in voltage control circuit coupled to the RF interface.

In another aspect, the invention is a built-in, burn-in self test circuit provided on a semiconductor wafer die. The circuit includes a device interface outputting voltage controls to induce a stress in selected components of a device; and an RF interface including a power rectifier and a signal demodulator.

In a still further aspect, the invention is an apparatus for burn-in self testing of a device. The apparatus includes a test chamber, a transport mechanism in the test chamber, a temperature control apparatus in the test chamber; and an RF transponder in the chamber. The apparatus may further include a test controller coupled to at least the temperature control apparatus and the RF transponder.

In another aspect, the invention is a method for manufacturing a semiconductor device. The method includes the steps of fabricating a plurality of devices on a semiconductor wafer; performing burn-in self testing of each of the devices by coupling power and control signals to the wafer via an RF signal; testing the devices; and separating the devices from the wafer.

In another aspect, a non volatile memory system is provided. The system includes an array of storage elements and control circuitry, a BIST circuit coupled to the control circuitry; and an RF interface coupled to the BIST circuit.

Various aspects of the present invention can be accomplished using hardware, software, or a combination of both hardware and software. The software used for the present invention is stored on one or more processor readable storage media including hard disk drives, CD-ROMs, DVDs, optical disks, floppy disks, tape drives, RAM, ROM or other suitable storage devices. In alternative embodiments, some or all of the software can be replaced by dedicated hardware including custom integrated circuits, gate arrays, FPGAs, PLDs, and special purpose computers.

These and other objects and advantages of the present invention will appear more clearly from the following description in which the preferred embodiment of the invention has been set forth in conjunction with the drawings.

### BRIEF DESCRIPTION OF THE DRAWINGS

FIG. 1 is a block diagram of one embodiment of a non-volatile memory system in which the various aspects of the present invention are implemented.

FIG. 2 illustrates an example of an organization of a memory array.

FIG. 3 illustrates a top view of a semiconductor wafer having a plurality of die formed thereon.

FIG. 4A illustrates an enlarged view of a corner of one of said die shown in FIG. 3.

FIG. 4B is an enlarged view of a portion of the wafer of FIG. 3 wherein the BIST circuit and its associated antenna is provided in the scribe line.

FIG. 4C is an enlarged view of a portion of the wafer of FIG. 3 wherein the BIST circuits of adjacent dies share an associated antenna provided in the scribe line.

FIG. 4D is a side view of an antenna formed in a scribe line.

FIG. 4E is a perspective view of a single layer antenna.

FIG. 5 is a block diagram of a BIST circuit formed in accordance with the present invention.

FIG. 6 is a flowchart of an exemplary manufacturing process in accordance with the present invention.

FIGS. 7A and 7B are illustrations of exemplary apparatus for performing the process illustrated in FIG. 8.

FIG. 8 is a flowchart illustrating a burn-in process in accordance with the present invention.

### DETAILED DESCRIPTION

In accordance with the invention, a unique process for ensuring reliability in integrated circuits is provided. The invention provides a system and method for performing tests on a circuit die using an RF signal to deliver control and power to an on-wafer built-in self test (BIST) circuit. One example of a test which may be performed is a burn-in test, described herein. However, it will be understood additional types of tests may be performed using the method of the present invention. The circuit may be provided in the die or an alternative part of the wafer. An on-wafer RF antenna serves as the inductive secondary coil of the RF system which delivers power and instructions to the BIST circuit. Multiple BIST circuits may be provided, with an antenna associated with each circuit. In a further aspect, the antenna may be provided in metal layers in scribe lines separating the various die.

The invention has applications in various integrated circuit technologies, including various applications of die-level markets, multi-chip modules, and integrated circuit products. By way of example only, the invention will be described with respect to its use in a flash memory system having a memory cell array. It will be understood that the device to be tested may comprise any number of different exemplary devices, and the invention is not limited to applications with memory devices. Modifications to the specific aspects of the invention to adapt the principles of the invention to various technologies now known or later developed will be apparent to those of average skill in the art.

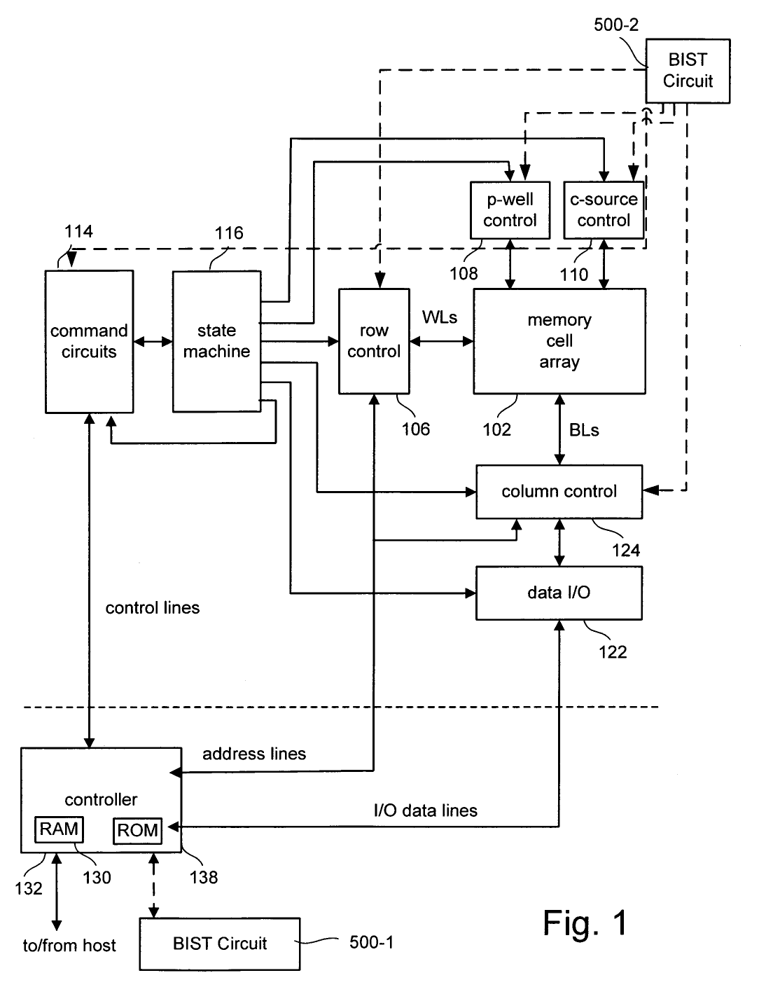

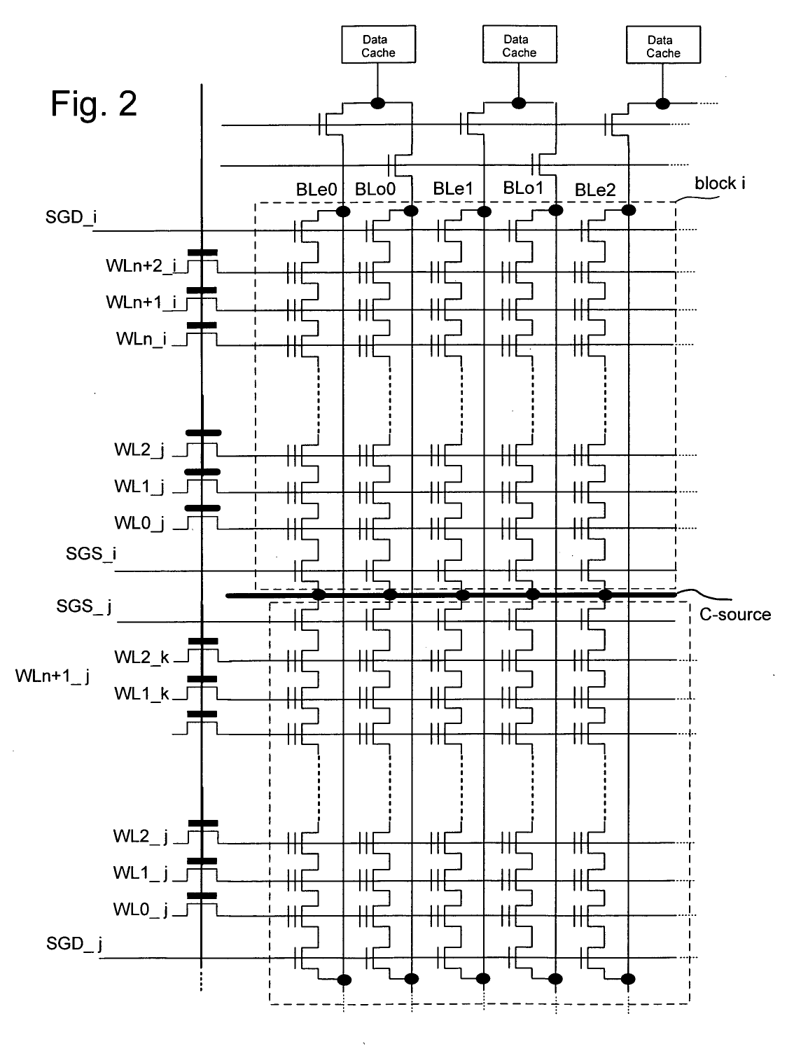

In accordance with the foregoing, FIGS. 1 and 2 show the basic construction of a flash memory system. FIG. 1 is a block diagram of one embodiment of a flash memory system. Memory cell array 102 is controlled by column control circuit 124, row control circuit 106, c-source control circuit 110 and p-well control circuit 108. Column control circuit 124 is connected to the bit lines of memory cell array 102 for reading data stored in the memory cells, for determining a state of the memory cells during a program operation, and for controlling potential levels of the bit lines to promote the programming or to inhibit the programming. Row control circuit 106 is connected to the word lines to select one of the word lines, to apply read voltages, to apply program voltages and to apply an erase voltage. C-source control circuit 110 controls a common source line (labeled as “C-source” in FIG. 2) connected to the memory cells. P-well control circuit 108 controls the p-well voltage.

The data stored in the memory cells are read out by the column control circuit 124 and are output to external I/O lines via data input/output buffer 122. Program data to be stored in the memory cells are input to the data input/output buffer 122 via the external I/O lines, and transferred to the column control circuit 104. The external I/O lines are connected to controller 118.

Command data for controlling the flash memory device is input to controller 138. The command data informs the flash memory of what operation is requested. The input command is transferred to state machine 116, which controls column control circuit 124, row control circuit 106, c-source control 110, p-well control circuit 108 and data input/output buffer 122. State machine 116 can also output status data of the flash memory such as READY/BUSY or PASS/FAIL.

Controller 138 is connected or connectable with a host system such as a personal computer, a digital camera, personal digital assistant, etc. Controller 138 communicates with the host in order to receive commands from the host, receive data from the host, provide data to the host and provide status information to the host. Controller 138 converts commands from the host into command signals that can be interpreted and executed by command circuits 114, which is in communication with state machine 116. Controller 138 typically contains buffer memory for the user data being written to or read from the memory array.

One exemplary memory system comprises one integrated circuit that includes controller 138, and one or more integrated circuit chips that each contain a memory array and associated control, input/output and state machine circuits. In one embodiment, the memory arrays and controller circuit are together on one integrated circuit chip. The memory system may be embedded as part of the host system, or may be included in a memory card (or other package) that is removably inserted into the host systems. Such a removable card may include the entire memory system (e.g. including the controller) or just the memory array(s) and associated peripheral circuits (with the Controller being embedded in the host). Thus, the controller can be embedded in the host or included within a removable memory system.

The structure of the memory cell array 102 is shown in FIG. 2. As one example, a NAND flash EEPROM is described.

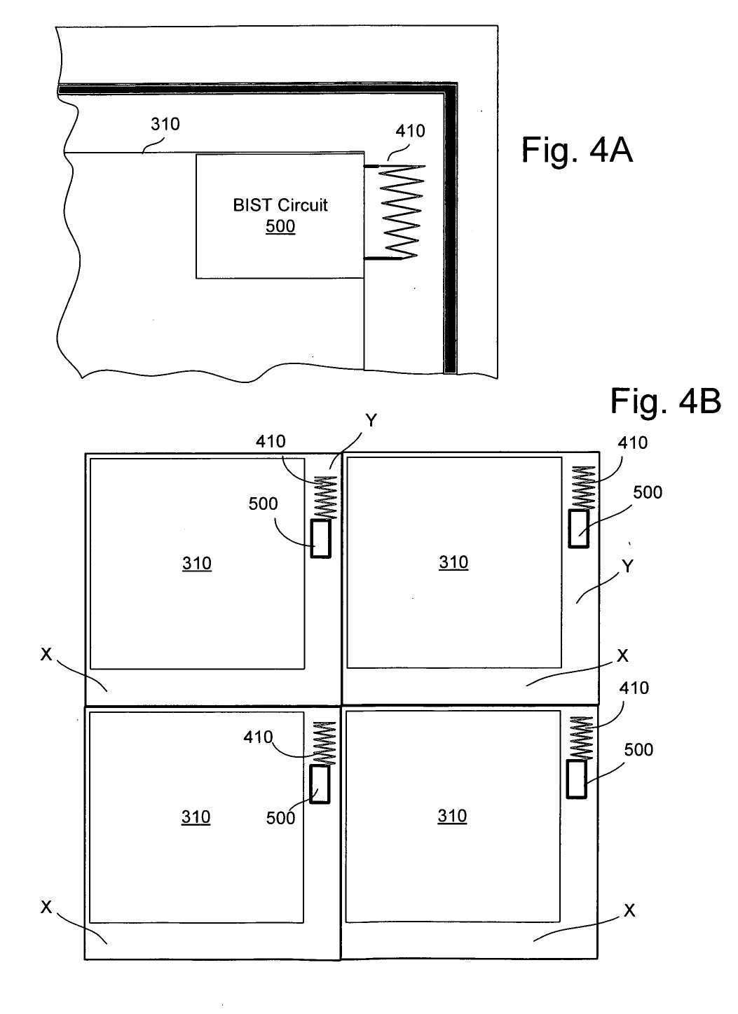

FIG. 2 shows NAND strings 202, 204, 206, 208, and 210 of a memory array having many more NAND strings. Each of the NAND strings of FIG. 4 includes two select transistors and a number of memory cells. For example, NAND string 202 includes select transistors 220 and 232, and memory cells 220, 222, 224, 226 and 228 and 230. Each string is connected to the source line by its select transistor (e.g. select transistor 232). A selection line SGS is used to control the source side select gates. The various NAND strings are connected to respective bit lines by select transistors, e.g. transistor 220, which are controlled by select line SGD. In other embodiments, the select lines do not necessarily need to be in common. As can be seen, each bit line and the respective NAND string comprises the columns of the array of memory cells. The word lines (WL2, WL1 and WL0) comprise the rows of the array.

Each word line also includes a high voltage transistor HV0, HV1, HV2 which comprise word line drivers for the memory array. To exemplary burn-in conditions for stressing the gate oxide of these transistors are detailed below as examples of stress conditions generated by the BIST circuit.

Bit lines are also divided into even bit lines (BLe) and odd bit lines (BLo). Memory cells are erased by raising the p-well to an erase voltage (e.g. 20 volts) and grounding the word lines of a selected block. The source and bit lines are floating. In read and verify operations, the select gates (SGD and SGS) and the unselected word lines (e.g., WL0, WL1 and WL2) are raised to a read pass voltage (e.g. 4.5 volts) to make the transistors operate as pass gates. The selected word line (e.g. WL2) is connected to a voltage, a level of which is specified for each read and verify operation in order to determine whether a threshold voltage of the concerned memory cell has reached such level. Operation of the aforementioned memory device is well known in the art.

Also shown in FIG. 1 is a built-in self test (BIST) circuit which controls performance of one or more built-in tests in response to a control input. The various embodiments of the BIST circuit and the functions thereof are described herein. In the example shown in FIG. 1, the BIST circuit is described as providing a built-in, burn-in test. This test seeks to reveal physical defects in the device. However, it should be understood that the BIST circuit can enable any memory failure tests as well, including the 0-1 test, checkerboard tests, columns and bars, sliding diagonal, walking 1's and 0's and the march test. In a memory device, the results of such tests can be written to a result block for evaluation at a later point in the process, as discussed below.

Two alternative configurations (500-1 and 500-2 ) for the BIST circuit for performing a wafer burn-in process are shown in FIG. 1. In a first configuration, represented by reference numeral 500-1, the BIST circuit is shown coupled to the controller 132. BIST circuit 500-1 interfaces with the controller 138 to instruct the controller to provide test voltages to various components of the system. A second configuration 500-2 of the BIST may be coupled directly to, for example, command circuits 114, row control 106, column control 124, p-well control 108 and/or c-source control 110. While both examples of BIST circuits (500-1 and 500-2 ) are shown, it will be understood that only one of the two circuits is required in the present invention. Specific implementations of the burn-in tests which may be performed by the BIST circuit may vary in accordance with the implementation of the invention and in accordance with the device undergoing burn-in. Other BIST circuit configurations and connections to the device may be needed, depending on the burn-in stress desired for the device under test.

In accordance with the present invention, power and control signals for the BIST circuit are provided by an RF signal received and converted on the device under test by an RF antenna and decoder circuit. Memory systems such as those described in FIGS. 1 and 2 may be manufactured in individual dies on a wafer. In one embodiment, the RF signal is received using a scribe line antenna formed in the wafer die scribe lines. Other embodiments of the antenna configuration may be utilized in accordance with the present invention and are discussed below. It should be understood that the BIST control circuit may have any number of configurations and complexity, depending on the design of the testing system and the device to be tested.

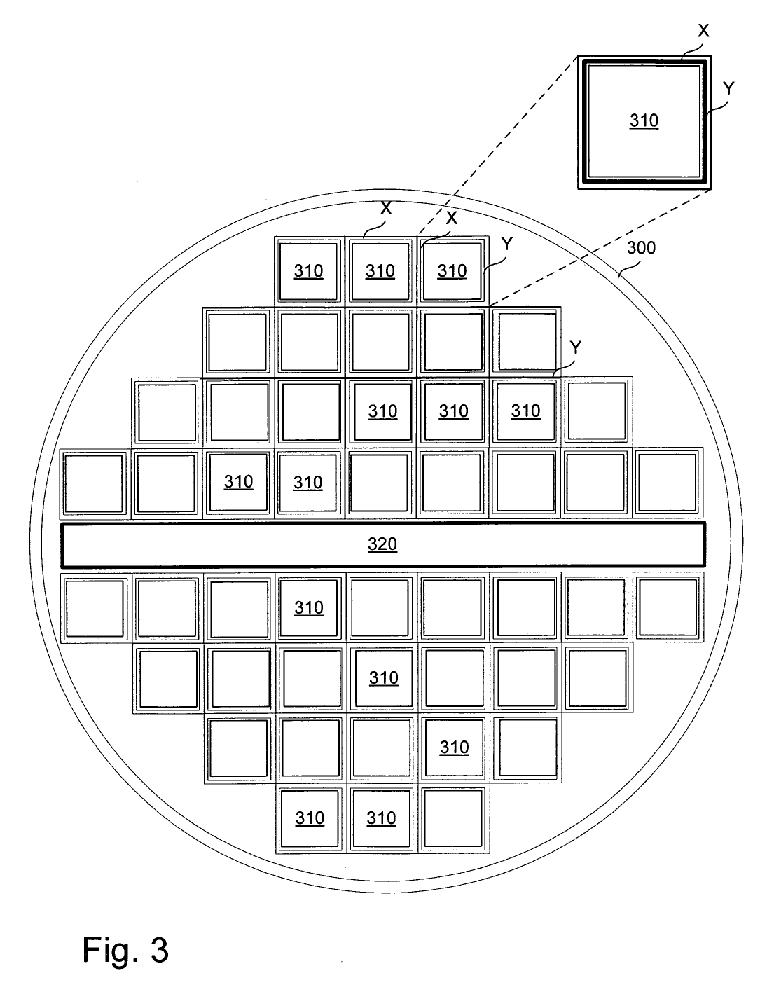

FIG. 3 shows a plurality of dies 310 arranged in a matrix, a plurality of vertical scribe lines X arranged in columns of the die matrix, and a plurality of horizontal scribe lines Y arranged in rows of the die matrix. A scribe line is used to scribe and break the semiconductor wafer into individual dies. In a typical semiconductor manufacturing process, the scribe lines X and Y may be associated with adjacent dies, and include testing circuits for adjacent dies. Metal layers may be formed in the scribe lines, and in accordance with the invention, as described below, are used in the present invention to form antennae for use in coupling an RF signal to a BIST circuit.

Wafer 300 is shown as including a test circuit area 320. However, in at least one embodiment of the present invention, no test circuit area 320 need be required. In such an embodiment, the test circuit area 320 may include additional dies.

A BIST circuit may be provided on the wafer, for example in the test circuit area 320, or in association with each individual die 310 as illustrated in the various embodiments in FIGS. 4A-4C. In accordance with the present invention, control for any number of physical or circuit tests is provided in the BIST circuit.

FIG. 4A shows one alternative location for BIST circuit 500 wherein the BIST circuit is provided in the circuit area of a die 310. The BIST circuit 500 has a connection to an RF antenna 410 located in the scribe line area. The RF antenna serves to couple power and test instructions transmitted “wirelessly” from a controller (not shown in the Figure) to the BIST circuit 500. In this unique feature of the present invention, issues in the prior art concerning how to connect power and control signals to the wafer under test (using, for example, sacrificial layers or interconnects), are eliminated, providing a greater potential throughput.

One antenna can serve a number of die, or multiple antenna may be provided, one for each die. FIG. 4A shows an individual antenna located in the vertical scribe line Y and circuit 500 within the circuit area of the die under test. FIG. 4B shows a further alternative of the present invention wherein individual antennas 410, one for each die, may be provided in adjacent scribe lines for the die, and the BIST circuit 500 is likewise provided in the vertical scribe line associated with the die. Another alternative is shown in FIG. 4C wherein a single antenna 410 is shared by two adjacent BIST circuits 500 in adjacent die. It should be understood that any number of circuits 500 may share a single antenna 410. Still further, one or more antennae may be provided in the test circuit area, and shared by individual BIST circuits associated with in one or more individual die.

In FIGS. 4A-4C, an antenna 412 is illustrated generally by a coil symbol. The antenna serves as a secondary winding of an inductive structure, and hence its construction should be specific to the signals passed thereto. In one embodiment, antenna 412 may be constructed using a number of metal layers in the scribe line. FIG. 4D shows a side view along the scribe line of a series of metal layers 412, 414, 416 connected by an interconnect structure 420 coupled to a substrate 430, In this embodiment, each metal layer serves as a turn in the antenna, allowing the antenna to received RF energy by means of induction. The antenna 412 is coupled to the BIST circuit by a substrate connection 435. In one embodiment, the antenna may be made of six turns implemented with the upper five metal layers of the scribe line. One example of an antenna includes that formed in accordance with the teachings presented in Bouvier, Renaudin, and Vivet “A New Contactless Smartcard IC using On-Chip Antenna and an Asynchronous Micro-Controller:” Solid-State Circuits, IEEE Journal 36, Issue: 7, July 2001 Pages 1101-1107.], fully incorporated by reference herein. In this example, the length of the die is 4 mm, and the area of the antenna is approximately 1.5 mm². However, numerous embodiments of antennae are suitable for use with the present invention. A single metal layer antenna 450 is shown in perspective view in FIG. 4E. Various embodiments of antennae suitable for use in the present invention may be derived from “The design of CMOS Radio-Frequency Integrated Circuits,” by Thomas H. Lee, Cambridge University Press, 2002.

While the antenna is suitable for receiving RF signals in a well known manner, the power and control signals must be decoded and used by the BIST circuit.

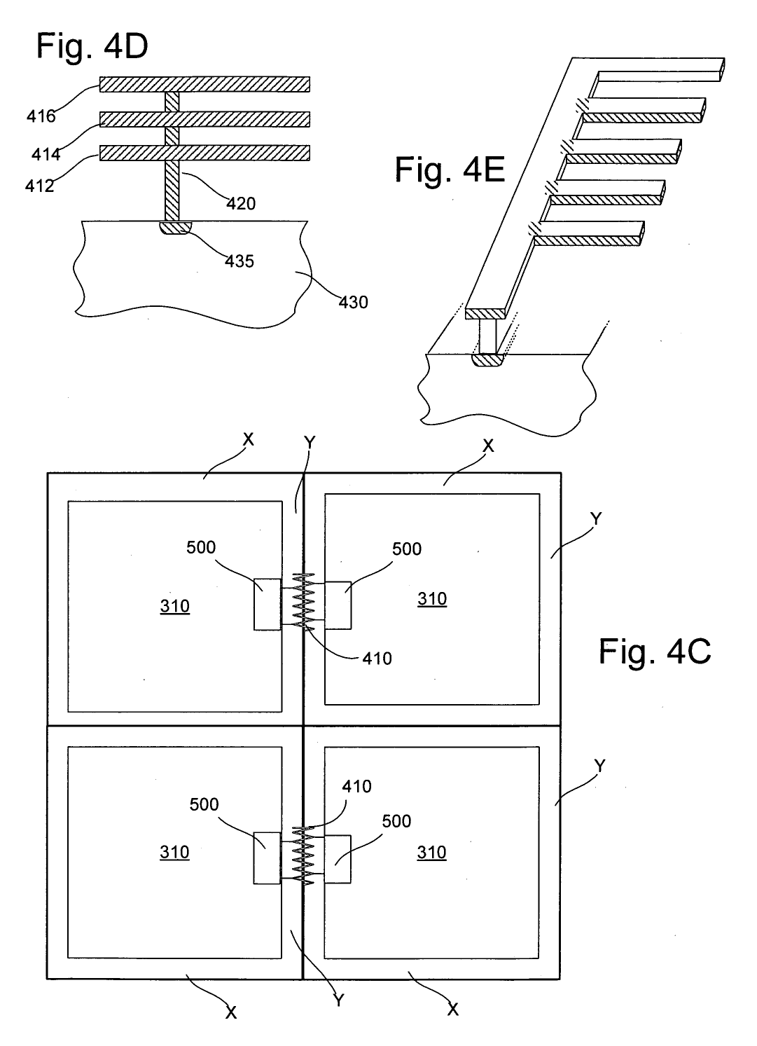

FIG. 5 is a functional block diagram of an exemplary BIST circuit. The BIST circuit includes an RF interface 510 coupled to the antenna 410, and a BIST controller interfacing with the controller 132, or directly with elements of the device under test. It will be recognized that the specific configuration of the controller is not germane to the characterization of the present invention, and will vary in configuration depending on the device to which it is coupled and the functions it is required to perform. At a minimum, the BIST circuit 500 transfers power and a test enable control signal to the BIST controller. An enable signal may start a pre-defined test sequence in the BIST controller. In such embodiments, the BIST controller may include one or more registers storing information to control stress testing in the device. In more complex embodiments, instructions, addressing and other more complex instructions may be transmitted to the interface. In such embodiments, for example, the interface provides not only data about which elements in the device to test, but also address information, clocking information, a reset signal, and other information. Hence, the RF interface can be relatively simple, or made complex, depending on the application.

The antenna 410 serves as an inductive coupling which will transmit both power and data through the air or a non metallic surface from an interface coil to the RF Interface. The RF interface may include a rectifier 510 and demodulator 514. The RF energy received by the antenna is converted in a DC voltage in order to power BIST controller using a full bridge rectifier 512. Modulating the current at two different frequencies as it passes through the primary coil allows data to be transmitted to the antenna, acting as a secondary coil in the inductive system, and decoded by the demodulator 514. When the RF interface 510 receives the current, it demodulates the signal and retrieves the data at the same time as it uses the transmitted power to activate its circuitry. Therefore, the advantage to this process is that it is able to transfer both information and power to a BIST circuit. In one embodiment, voltage regulation circuitry 516 may be provided to provide one or more voltage outputs to the BIST controller.

In one embodiment, the RF interface is a microcontroller such as that disclosed in Bouvier, Renaudin, and Vivet “A New Contactless Smartcard IC using On-Chip Antenna and an Asynchronous Micro-Controller:” (Id.) Because all RF energy is confined within the chamber, the RF frequency selected for operation can be any frequency for maximum efficiency within the distance of the

In one embodiment, the antenna may operate up to 1 m from the transponder with a communication speed of 4 baud/s. Data such as the test enable signal, or more complex information, may be provided to the RF interface by encoding it in the RF signal along with the power necessary to drive the RF interface. In general, the most popular methods used to encode data are Non-Return to Zero (NRZ) Direct, Differential Biphasic and Biphase_L. In NRZ, no data encoding is performed; the 1's and 0's are clocked from the data directly. For example, a low in the peak-detected modulation is a ‘0’ and a high is a ‘1’. Several different forms of differential biphasic are available, but in general the bit stream being clocked out of the data array is modified so that a transition always occurs on every clock edge, and 1's and 0's are distinguished by the transitions within the middle of the clock period. This method is used to embed clocking information to the bit stream; and because it always has a transition at a clock edge, it inherently provides some error correction capability. Biphase_L is a variation of biphasic encoding, in which there is not always a transition at the clock edge.

In one embodiment, the demodulator 514 includes clock recovery circuits which transmit additional data to the BIST controller. In one embodiment, the data signal can be as elementary as an “enable built-in test” signal, instructing the BIST controller to initiate a pre-determined test sequence, such as a burn-in sequence. Alternatively, the data may be more complex, and include instructions for a DAC provided in the BIST circuit, addressing information to select individual row or word lines for testing, or instructions to implement more complex functions of the BIST controller. In one example, the enable signal is output from the RF interface on the DATA line. Various embodiments of burn-in methods and BIST controllers are described below. Exemplary BIST control circuits are shown in U.S. Pat. Nos. 6,169,694 and 6,352,868, each of which are fully incorporated by reference herein. Other variations are possible. An in-circuit DAC may be provided to allow programming of various modes in the BIST responsive to specific device control signals.

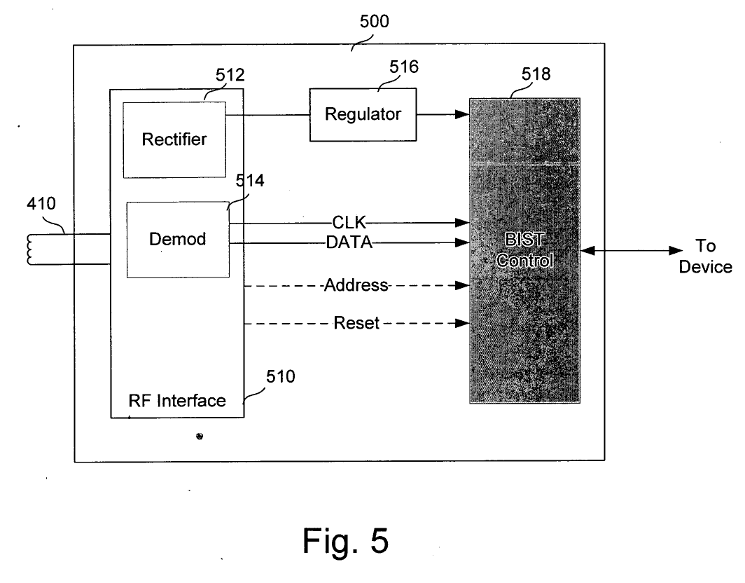

FIG. 6 illustrates a method for performing a wafer level built-in used in accordance with the present invention. In one embodiment where a burn-in test is being performed, any method suitable for burn-in testing is suitable, such as those described with respect to specifications such as MIL-STD-883-E or JESD22-A108-B (JEDEC Standard Temperature, Bias and Operating Life). Each such standard is used to determine the effects of bias conditions and temperature on solid state devices over time by simulating the devices operation condition in an accelerated way. Different particular methods will be applied to each type of technology or device.

As shown in FIG. 6, a wafer having a plurality of dies is introduced into an elevated or cooled environment in step 610. A specific example of a burn-in test is detailed below for one type of device. Typically this portion of the test will involve thermally heating the device for various periods of time while subsequent portions of the burn-in process are conducted. At step 620, circuit stress is initiated. Different voltages may be applied to stress various elements of the device, again depending on the device under test. Generally, all such stresses are conducted at elevated temperatures provided in step 610. Various tests may be conducted on different elements before the device is removed from the chamber. Next, a probe test is performed to detect any device failures at step 630. The probe test generally used automated test equipment for failures. Wafers discovered to experience problems at step 640 may be subject to repair or discarded. Next, the wafers are diced at step 650, packaged at step 660 and are ready for shipment at step 670. Repair may occur at the wafer level, or at the die level, in which case step 640 may follow.

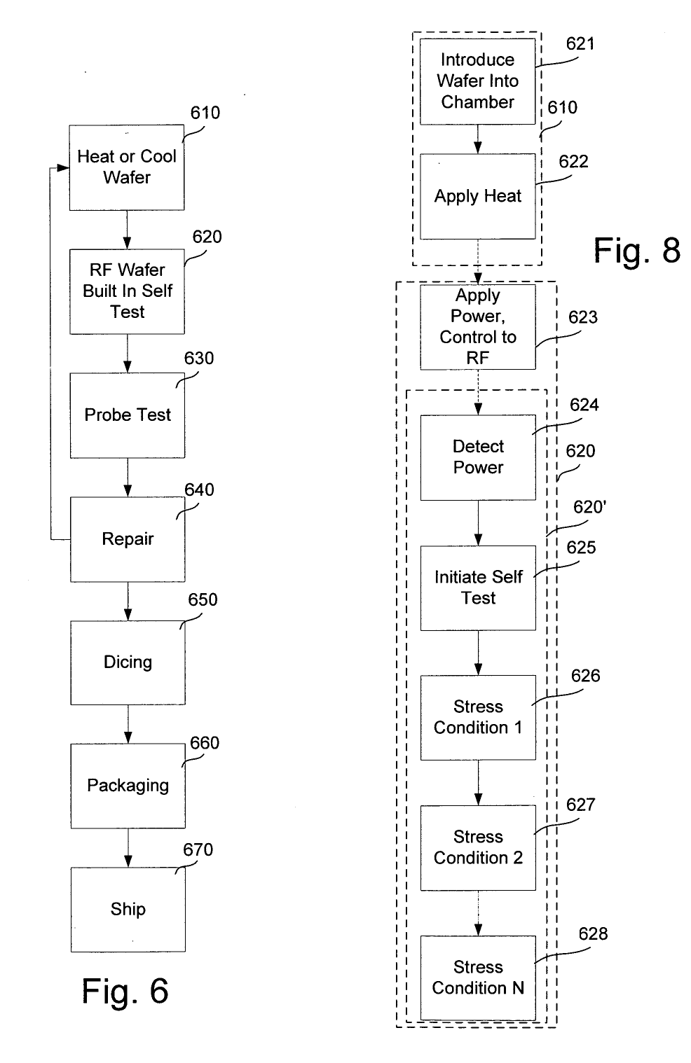

FIG. 7A shows an exemplary apparatus for performing the wafer level burn-in process in accordance with the present invention. Apparatus 700 includes an entry port 715 and exit port 725, which may in one embodiment comprise the same physical portal, a mechanism 735 for moving wafers into and out of the apparatus 700, and a heat or cooling source 710 which controls the ambient temperature of wafers 300 in the apparatus. Numerous alternatives to the transport mechanism are suitable for use in the present invention, as well as numerous types of heating and cooling sources. Also included in the apparatus 700 is an RF transponder coil 720 which transmits power and signals from a test controller 730. Coil 720 may comprise one or more turns and one or more coils positioned to communicate with antenna on the wafer(s) in the apparatus to conduct burn-in on the wafers in the apparatus. A test controller 730 includes a signal generator and data encoder to provide a modulated RF signal to the coil 720. A user interface 740 for controlling the test controller 730 may be provided.

Wafers 300 may be provided on a conveying apparatus to move each wafer through a testing process from an input end of the apparatus to an output end. In one embodiment, the system is similar to an etch chamber with RF residing inside the chamber, or as shown in FIG. 7, as a belt type drying conveyer.

FIG. 7B shows a second exemplary apparatus for performing built-in testing in accordance with the present invention. The chamber may comprise a single-wafer RF chamber such as a high density plasma (HDP) CVD system which includes a vacuum chamber, a vacuum pump 12, and a source RF (SRF) generator 32. Normally, deposition gases and liquids are supplied from gas sources and disperse deposition gases to a substrate 45 resting on a pedestal 44 within chamber 10. An inductively coupled plasma of the deposition gases can be formed adjacent to substrate 45 by RF energy applied to coiled antenna 26 from source RF generator. In accordance with the present invention, the source RF generator can be modified to provide RF signals suitable for engaging the BIST circuit on a wafer in the chamber during a test phase.

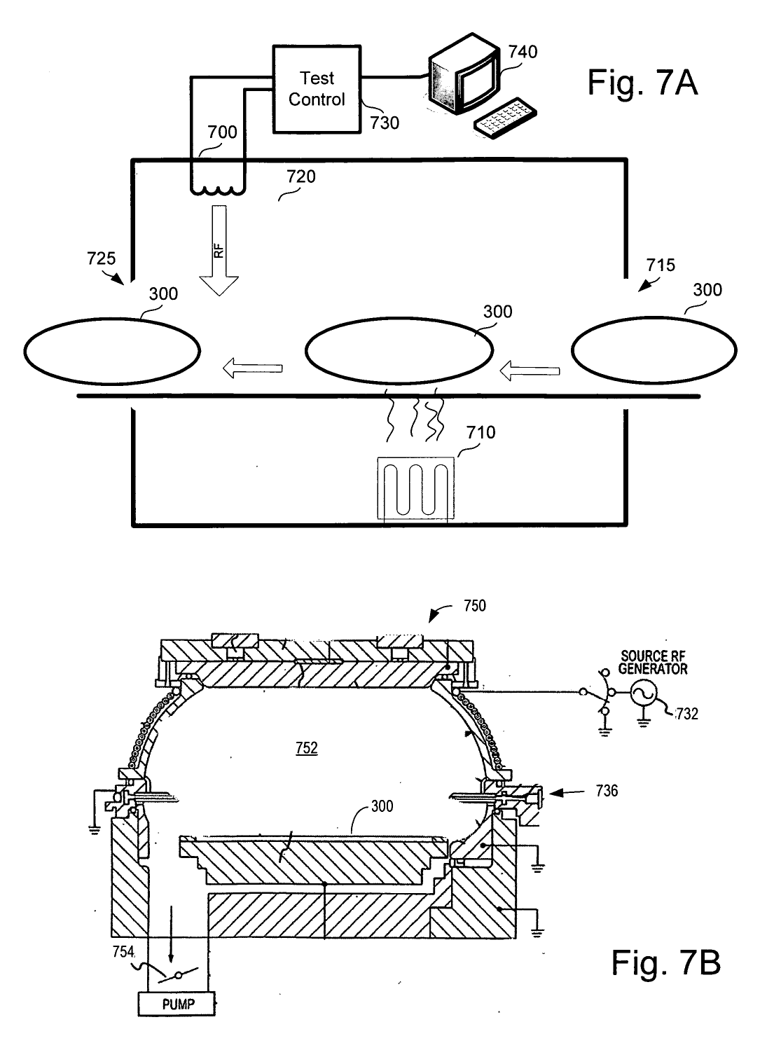

FIG. 8 illustrates an RF Wafer Level Burn-in Process in accordance with the present invention. It will be understood that the particular burn-in process is specific to the technology being tested, but in one example, during step 610, steps 621 and 622 may be performed, and during step 620, steps 623-628 may be performed. Initially, at step 621, a wafer including devices for which burn-in will be performed is placed in a test chamber. At step 622, ambient temperature control initiated in the apparatus. In one embodiment, the temperature at which burn-in is performed is approximately 125 degrees C. At step 623, under the control of the test controller, RF power and control information is provided to the coil 720 and transmitted to antennae on wafers 300 in the apparatus.

Steps 623-628 are performed on the wafer. At step 624, power and control signals are detected by the RF interface on the wafer. The power signal powers the decoder circuitry to interpret control signals from the test controller and such signals are transmitted to the BIST controller 518. At step 625 the BIST control initiates the burn-in self-test mode. As noted above, this initiation may be in response to an enable signal from the test controller, or may be a specific instruction to apply specific voltages to elements on the device under test. Subsequently, a number of burn-in tests at steps 626-628 may be performed. In one embodiment, steps 626-628 are run automatically by controller 518. In an alternative embodiment, they are run according to control signals specifically provided by test controller 740.

Referring to FIG. 2, in one example where a chip designer desired testing of the high-voltage transistors coupled to each word-line (WL) in a memory array, step 626-628 may comprise applying test voltages as indicated in Table 1, where each row in table comprises a separate step 626, 627:

TABLE 1

| | | HV | HV | BLe/ | Sub- | | |
|---|---|---|---|---|---|---|---|
| Step | Csource | Source | (gate) | BLo | strate | SGD_i | SGS-i |
| 626 | Ground | Ground | Hi | Ground | Float | Float | Float |
| | | | (˜5 v) | | | | |
| 627 | Ground | 20 v | 0 v | Float | Float | Float | Float |
| 628 | Ground | Hi | Hi | Ground | Ground | Hi | Hi |

In the foregoing table, steps 626 and 627 provide stress testing for the HV transistor gate oxide in the circuit of FIG. 2. Step 628 provides testing for peripheral circuits not shown in FIG. 2. While the above stress conditions are exemplary, any number of sets of conditions may be provided. Typical burn-in sequences can last from minutes to hours or days, with the total sequence for all burn-in tests for a memory device being, for example, on the order of several hours.

After the burn in sequence, in a further unique aspect of the present invention, a novel wafer fabrication sequence is provided. Wafer fabrication using the BIST process provides a unique and robust product. The present invention eliminates the need for custom whole wafer probe cards. Typically, such probecards are manufactured for each type of wafer undergoing the manufacturing process, and the cost of such probe cards is huge. Through the use of a contact free mechanism of transmitting power and control signals to the device under test, the present invention eliminates this excessive cost. Moreover, capacity can be increased since wafers can be more rapidly transported into and out of the testing apparatus, since no physical connection to the wafer is required for burn-in.

In yet another unique aspect of the invention, one only needs 3-4 signals to achieve built-in testing for each die. Such signals are advantageously transmitted over the RF signal.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

1. A method for performing a wafer-level test sequence, comprising:
providing the wafer into a test chamber; and
outputting a power and a test initiation signal to a wafer via a wireless signal.

2. The method of claim 1 wherein the test is a burn-in test.

3. The method of claim 1 wherein the step of providing includes providing a plurality of wafers into the test chamber, and said step of outputting including outputting to said plurality of wafers.

4. The method of claim 1 wherein said step of outputting includes outputting a signal initiating a device stress test sequence on the wafer.

5. The method of claim 1.0 wherein the signal is a test enable signal.

6. The method of claim 4 wherein the step of outputting includes encoding the test initiation signal.

7. The method of claim 4 where the signal includes instructions to provide voltages to specific elements on the wafer.

8. The method of claim 1 wherein the step of outputting comprises generating an RF signal in the chamber.

9. The method of claim 1 wherein the method further includes heating the wafer in the chamber.

10. The method of claim 1 wherein the method further includes providing a built-in burn-in test circuit on the wafer coupled to devices provided on the wafer.

11. A method for providing a built-in test process, comprising:
providing a built-in test circuit on the wafer; and
providing an RF interface on the wafer coupled to the built-in test circuit.

12. The method of claim 11 wherein the step of providing a built-in test circuit on the wafer includes providing a power extraction component and a demodulator.

13. The method of claim 12 wherein the power extractor is a full wave rectifier.

14. The method of claim 12 wherein the demodulator includes in interface with the built-in test circuit to provide a control signal to the built-in test circuit.

15. The method of claim 14 wherein the demodulator provides an enable control signal.

16. The method of claim 14 wherein the demodulator decodes an encoded enable control signal.

17. The method of claim 11 wherein the step of providing a built-in test circuit includes providing at least one BIST circuit in a test circuit area of the wafer.

18. The method of claim 11 wherein the step of providing a built-in test circuit includes providing at least one BIST circuit in a die area of the wafer.

19. The method of claim 11 wherein the step of providing a built-in test circuit includes providing at least one BIST circuit in a device subject to burn-in within a die circuit area of the wafer.

20. The method of claim 11 wherein the method further includes the step of conducting a burn-in self test of at least one device on the wafer responsive to a signal provided to the RF interface.

21. The method of claim 20 wherein the step of conducting a burn-in self test includes stressing elements of a device under at least a first set of voltage conditions.

22. The method of claim 21 wherein the step of conducting a burn-in self test includes stressing said elements under at least a second set of voltage conditions.

23. The method of claim 11 further including the step of providing an at least one antenna on the wafer.

24. The method of claim 23 further including the step of providing a plurality of antennae on the wafer.

25. The method of claim 23 wherein the step of providing a plurality of antennae on the wafer includes providing at least one antenna for each semiconductor device manufactured in a die on the wafer.

26. A semiconductor wafer, comprising:
at lease one built-in test control circuit coupled to a device on the wafer; and
an RF interface coupled to provide power and a data signal to the BIST circuit.

27. The apparatus of claim 26 wherein a plurality of devices are provided in the wafer and wherein a built-in test control circuit is provided for each device on the wafer.

28. The apparatus of claim 27 wherein each test control circuit is incorporated into said device.

29. The apparatus of claim 27 wherein each test control circuit is provided in a test circuit area of the wafer and coupled to at least one of said plurality of devices by a connector.

30. The apparatus of claim 26 wherein a plurality of devices are provided on the wafer and wherein said at least one built-in test control circuit is provided in a test circuit area of the wafer and connected to at least one device by a conductor.

31. The apparatus of claim 26 further including an antenna coupled to said RF interface.

32. The apparatus of claim 31 wherein a plurality of devices are provided on the wafer and at least one antenna is associated with each of said plurality of devices.

33. The apparatus of claim 32 wherein at least one of said antennae is provided in a scribe line surrounding said die.

34. The apparatus of claim 26 wherein the RF interface includes a power rectifier.

35. The apparatus of claim 26 wherein the RF interface includes a demodulator.

36. The apparatus of claim 26 wherein each built in test control circuit includes at least one pre-defined stress condition.

37. The apparatus of claim 36 wherein each BIST includes a plurality of pre-defined stress conditions.

38. The apparatus of claim 36 wherein the pre-defined stress condition is enabled by a data signal provided to the RF interface.

39. A semiconductor wafer, including a plurality of dies, each die separated by a scribe line, comprising:
at least on RF interface circuit provided on the wafer;
at least one scribe line RF antenna coupled to the at least one RF interface circuit; and
at least one burn-in voltage control circuit coupled to the RF interface.

40. The wafer of claim 39 wherein the RF interface includes a power rectifier and a demodulator.

41. The wafer of claim 40 wherein power fro the BIST circuit is provided by the power rectifier.

42. The wafer of claim 39 wherein a plurality of scribe line antennas are provided, one associated with each of said plurality of dies.

43. The wafer of claim 42 wherein each die includes a device, and one of said plurality of scribe line antennas is associated with each die.

44. The wafer of claim 39 wherein wafer includes a plurality of RF interfaces each associated with one of said plurality of scribe line antennas.

45. The wafer of claim 44 further including a plurality of burn-in voltage control circuits, each associated with one of said devices in said die.

46. The wafer of claim 39 wherein each burn-in voltage control circuit includes a predefined stress mode for an associate device in one of said die.

47. A built-in self test circuit provided on a semiconductor wafer die, comprising:
a device interface outputting voltage controls to induce a stress in selected components of a device; and
an RF interface including a power rectifier and a signal demodulator.

48. The circuit of claim 47 wherein a plurality of dies are provided in the wafer and wherein a built-in stress control circuit is provided for each die on the wafer.

49. The circuit of claim 48 wherein each control circuit is incorporated into said device.

50. The circuit of claim 47 further including an antenna coupled to said RF interface.

51. The circuit of claim 50 wherein said antenna is formed in a series of metal layers in a scribe line surrounding said die.

52. The apparatus of claim 47 wherein each built-in self test circuit includes at least one pre-defined stress condition.

53. An apparatus for burn-in self testing, comprising:
a test chamber;
a transport mechanism in the test chamber;
a temperature control apparatus in the test chamber; and
an RF transponder in the chamber.

54. The apparatus of claim 53 further including a test controller coupled to at least the temperature control apparatus and the RF transponder.

55. The apparatus of claim 54 wherein the test controller includes instructions generating an RF signal output by said transponder to provide a power and test control signal in the chamber.

56. The apparatus of claim 54 wherein the test controller includes an encoder generating an encoded test control signal output by the transponder.

57. A method for manufacturing a semiconductor device, comprising:
fabricating a plurality of devices on a semiconductor wafer;
performing built-in self testing of each of the devices by coupling power and control signals to the wafer via an RF signal;
testing the devices; and
separating the devices from the wafer.

58. The method of claim 57 wherein the step of performing comprises the steps of:
providing the wafer into a burn-in chamber; and
outputting a power and a test initiation signal to a wafer via a wireless signal.

59. The method of claim 58 wherein said step of outputting includes outputting a signal initiating a device stress test sequence on the wafer.

60. The method of claim 59 wherein the step of outputting comprises generating an RF signal in the chamber.

61. The method of claim 57 wherein the step of performing includes heating the wafer in the chamber.

62. A non volatile memory system, comprising:
an array of storage elements and control circuitry;
a BIST circuit coupled to the control circuitry; and
an RF interface coupled to the BIST circuit.
